(19) United States
(12) Patent Application Publication
(10) Pub. No.: US 2006/0176747 A1
(43) Pub. Date: Aug. 10, 2006

(54) Circuit for interfacing local bitlines with global bitline

(75) Inventors: Paul A. Bunce, Poughkeepsie, NY (US); John D. Davis, Wallkill, NY (US); Donald W. Plass, Poughkeepsie, NY (US)

Correspondence Address: CANTOR COLBURN LLP-IBM POUGHKEEPSIE, 55 GRIFFIN ROAD SOUTH, BLOOMFIELD, CT, 06002, US

(73) Assignee: INTERNATIONAL BUSINESS MACHINES CORPORATION, ARMONK, NY (US)

(21) Appl. No.: 11/054,296

(22) Filed: Feb. 9, 2005

(51) Int. Cl. G11C 7/00

(52) U.S. Cl. 365/203

(57) ABSTRACT

A circuit for interfacing local bitlines to a global bitline. The circuit includes a first device having an input coupled to a first local bitline in a first memory sub-array. A second device has an input coupled to a second local bitline in a second memory sub-array. An interface line is coupled to an output of the first device and coupled to an output of the second device. A precharge device is coupled to the interface line, the precharge device coupling the interface line to ground in response to a precharge signal. A global output device has an input coupled to the interface line and an output coupled to the global bitline.

### FIELD OF THE INVENTION

This invention relates to accessing memory arrays, and in particular, to a circuit for interfacing local bitlines with a global bit line.

### BACKGROUND

FIGS. 1A and 1B illustrate a high performance, low power domino SRAM design including multiple local cell groups such as that shown in U.S. Pat. No. 6,657,886, the entire contents of which are incorporated herein by reference. As shown in FIG. 1A, each cell group includes multiple SRAM cells 1-N and local true and complement bitlines LBLT and LBLC. Each SRAM cell includes a pair of inverters that operate together in a loop to store true and complement (T and C) data. The local true bitline LBLT and the local complement bitline LBLC are connected to each SRAM cell by a pair of wordline N-channel field effect transistors (NFETs) to respective true and complement sides of the inverters. A WORDLINE provides the gate input to wordline NFETs. A particular WORDLINE is activated, turning on respective wordline NFETs to perform a read or write operation.

As shown in FIG. 1B, the prior art domino SRAM includes multiple local cell groups 1-M. Associated with each local cell group are precharge true and complement circuits coupled to the respective local true and complement bitlines LBLT and LBLC, write true and write complement circuits, and a local evaluate circuit. Each of the local evaluate circuits is coupled to a global bitline labeled 2ND STAGE EVAL and a second stage inverter that provides output data or is coupled to more stages. A write predriver circuit receiving input data and a write enable signal provides write true WRITE T and write complement WRITE C signals to the write true and write complement circuits of each local cell group.

A read occurs when a wordline is activated. Since true and complement (T and C) data is stored in the SRAM memory cell, either the precharged high true local bitline LBLT will be discharged if a zero was stored on the true side or the precharged high complement bitline LBLC will be discharged if a zero was stored on the complement side. The local bitline, LBLT or LBLC connected to the one side will remain in its high precharged state. If the true local bitline LBLT was discharged then the zero will propagate through one or more series of domino stages eventually to the output of the SRAM array. If the true local bitline was not discharged then no switching through the domino stages will occur and the precharged value will remain at the SRAM output.

To perform a write operation, the wordline is activated as in a read. Then either the write true WRITE T or write complement WRITE C signal is activated which pulls either the true or complement local bitline low via the respective write true circuit or write complement circuit while the other local bitline remains at its precharged level, thus updating the SRAM cell.

As noted above, local bitlines are coupled to a global bitline. Existing designs dot bitlines from memory sub-arrays using extra components. There is a need in the art for a circuit for dotting bitlines from multiple sub-arrays using less components to provide higher density, faster accessing and less leakage current.

### SUMMARY OF THE INVENTION

Embodiments of the invention include a circuit for interfacing local bitlines to a global bitline. The circuit includes a first device having an input coupled to a first local bitline in a first memory sub-array. A second device has an input coupled to a second local bitline in a second memory sub-array. An interface line is coupled to an output of the first device and coupled to an output of the second device. A precharge device is coupled to the interface line, the precharge device coupling the interface line to ground in response to a precharge signal. A global output device has an input coupled to the interface line and an output coupled to the global bitline.

Another embodiment of the invention is a circuit for interfacing local bitlines to a global bitline. The circuit includes a first PFET having a gate node coupled to a first local bitline in a first memory sub-array. A second PFET has a gate node coupled to a second local bitline in a second memory sub-array. An interface line is coupled to a drain node of the first PFET and coupled to a drain node of the second PFET. A precharge NFET has a drain node coupled to the interface line, the precharge NFET receiving a precharge signal on a gate node and coupling the interface line to ground in response to a precharge signal. A global output NFET has a gate node coupled to the interface line and a drain node coupled to the global bitline.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1A illustrates an exemplary conventional SRAM cell;

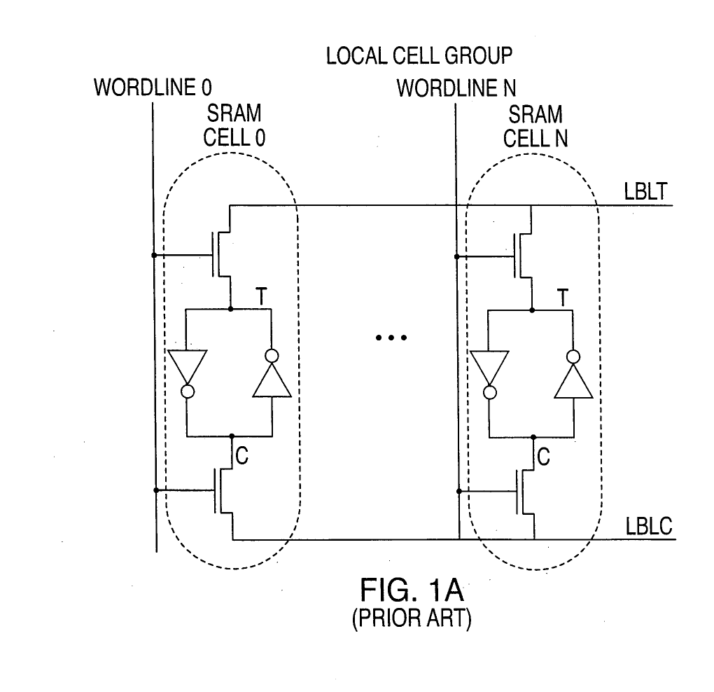

FIG. 1B illustrates an exemplary domino SRAM;

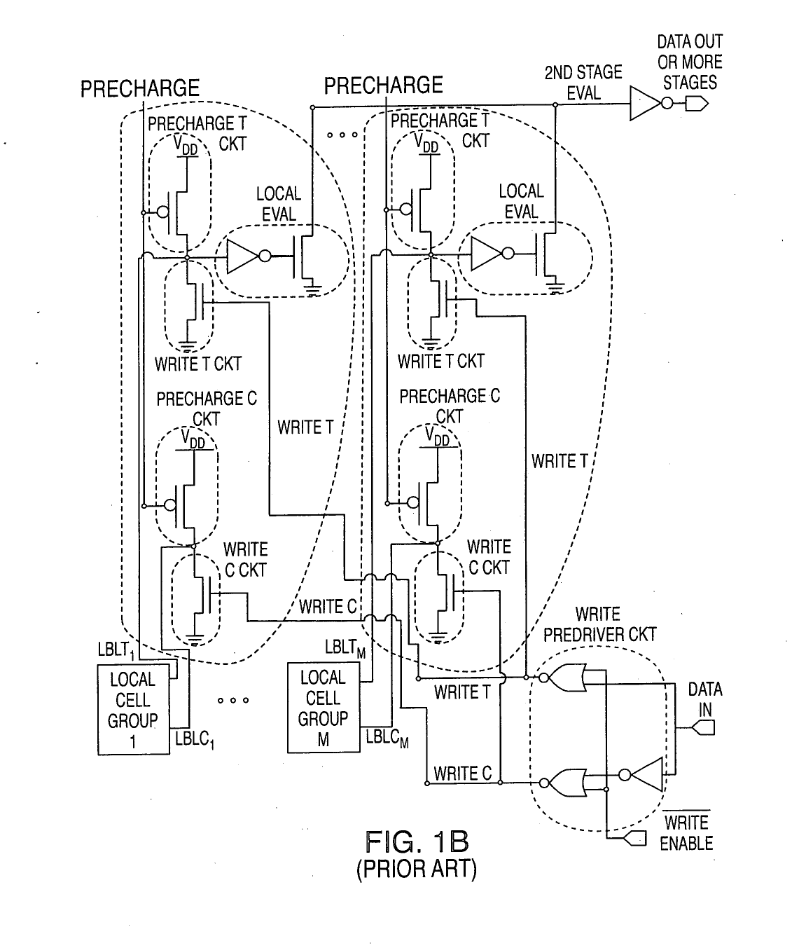

FIG. 2 is a block diagram of a synchronization circuit for use with a memory array;

FIG. 3 depicts two cell blocks interfaced at a global bitline interface;

FIG. 4 depicts a local to global bitline interface in an exemplary embodiment;

FIG. 5 depicts a local to global bitline interface in an alternate embodiment; and

FIG. 6 depicts a local to global bitline interface in an alternate embodiment.

The detailed description explains the preferred embodiments of the invention, together with advantages and features, by way of example with reference to the drawings.

### DETAILED DESCRIPTION OF THE INVENTION

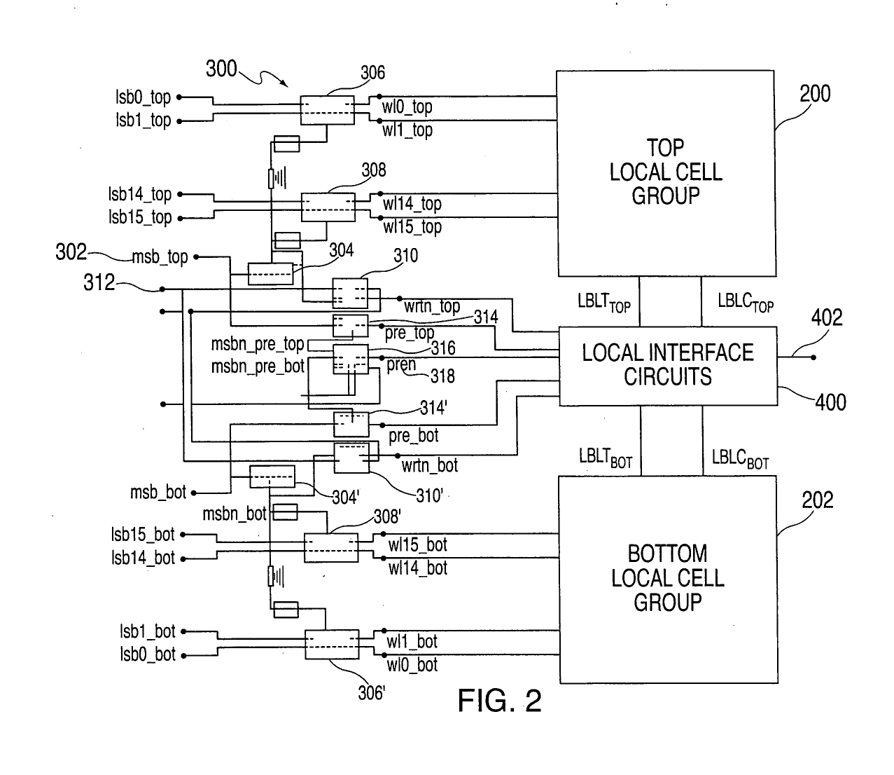

FIG. 2 is a block diagram of a synchronization circuit 300 for use with a memory array. The synchronization circuit 300 is divided into a top and bottom portion, corresponding to the top local cell group 200 and the bottom local cell group 202 of a memory array that is divided into a top sub-array and a bottom sub-array. Local interface circuits 400 access the top local cell group 200 or the bottom local cell group 202 over bitlines LBLTtop, LBLCtop, LBLTbot and LBLCbot and output a global bitline 402.

Operation of the synchronization circuit 300 will be made with reference to the top portion, with corresponding elements in the bottom portion operating in the same manner. The synchronization circuit 300 generates a number of array signals in response to a synchronization signal. In the embodiment of FIG. 2, the synchronization signal is a most significant bit signal 302 labeled msb_top. The most significant bit signal 302 is from a decoded address word.

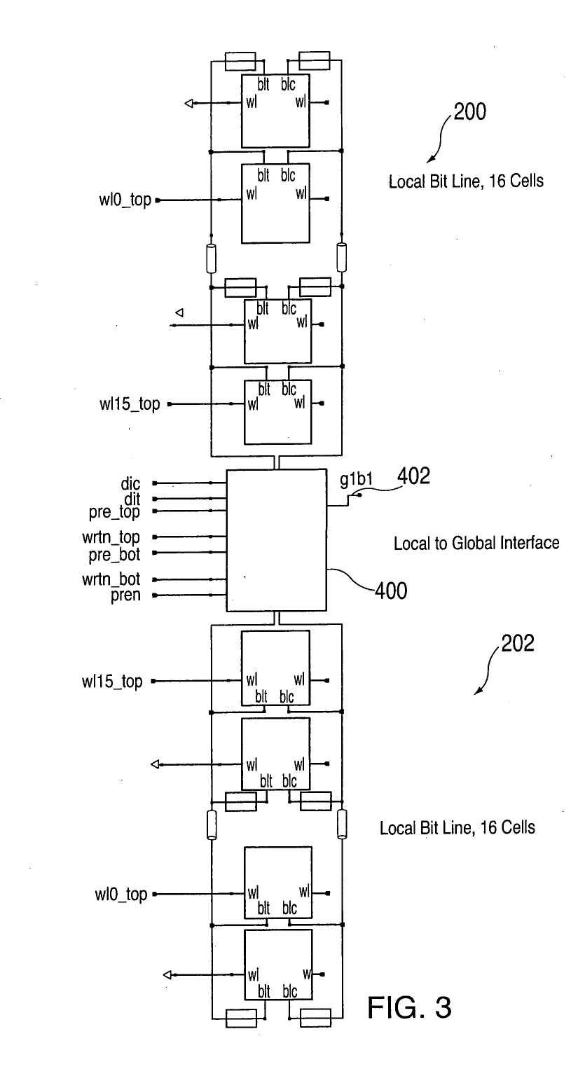

The most significant bit signal 302 is provided to an inverter 304 that generates the compliment of the most significant bit signal 302, labeled msbn_top. The compliment of the most significant bit signal 302 is provided to word drivers 306 and 308 to enable the generation of wordline select signals output by word drivers 306 and 308. The wordline signal is the row access signal that activates memory cells in top local cell group 200. The wordline drivers 306 and 308 are described in further detail with reference to FIG. 3.

The compliment of the most significant bit signal 302, labeled msbn_top, is also provided to a write driver 310. The write driver 310 generates a write signal based on the compliment of the most significant bit signal 302 and an external write enable signal 312 labeled. The write driver 310 is an AND of a write enable signal 312 with msbn_top. The write driver 310 outputs a write enable signal labeled wrtn_top. The write enable signal is a row signal that enables (e.g., low) or disables (e.g., high) a write operation.

The most significant bit signal 302 is also provided to a buffer 314 that outputs a local precharge signal, labeled pre_top. A low logic level on the local precharge signal precharges the local bitlines to their standby state. A high logic level on the local precharge signal turns off the precharge and allows the bitlines to be driven by the cell (for a read) or a data driver (for a write).

The buffer 314 also outputs a compliment of the most significant bit signal, labeled msbn_pre_top. The compliment of the most significant bit signal is generated by an inverter stage in buffer 314. The compliment of the most significant bit signal is provided to a local precharge logic 316, which generates a second precharge signal 318. The precharge signal is a memory array row signal for regulating read operations. The local precharge logic performs an AND operation between the top compliment of the most significant bit signal and the bottom compliment of the most significant bit signal which is generated at buffer 314′. In an alternate embodiment, the msbn_top signal from inverter 304 is input to the precharge logic 316. This eliminates the need to generate the msbn_pre_top signal.

FIG. 3 is a block diagram of a system for interfacing local bitlines to a global bitline. Memory cells from the top sub-array 200 and the bottom sub-array 202 are coupled to a local to global interface 400. FIG. 3 shows the local to global interface 400 receiving the local precharge top, local precharge bottom, write enable top, write enable bottom and precharge signal. Also shown in FIG. 3 is a data in true signal, labeled dit, and a data in compliment signal, labeled dic. Data in true and data in compliment are used to write to a memory cell.

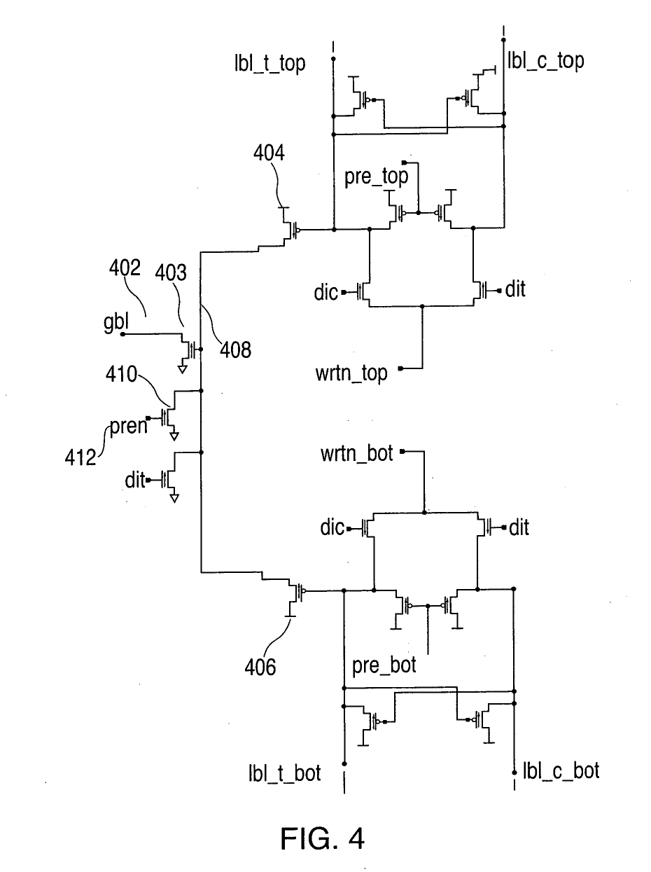

FIG. 4 depicts a local to global bitline interface in an exemplary embodiment. The global bitline 402 is connected to the local bitlines lbl_t_top and lbl_t_bot through PFET devices 404 and 406, respectively. Either the top sub-array is read or the bottom sub-array is read, but not both at the same time. The global bitline is precharged to a logic 1.

The local bitlines from the top and the bottom sub-arrays are connected to the inputs (e.g., gate node) of PFETs 404 and 406. Outputs (e.g., drain nodes) of the PFETs 404 and 406 are connected to an interface line 408. An NFET global output device 403 has an input (e.g., gate node) coupled to the interface line 408 and an output (e.g., drain node) driving to the global bit line 402. When the precharge signal 412 is high, NFET precharge device 410 pulls the interface line 408 to ground preventing output on the global bitline 402. When precharge signal is low, the output at global bitline 402 is controlled by one of PFET 404 and PFET 406. When the top sub-array cell stores a logic 0, PFET 404 is conductive and drives interface line 408 high. This causes NFET global output device 403 to turn on and couple the global bit line 402 to ground. When the top sub-array cell stores a logic 1, PFET 404 is not conductive, and the global bitline 402 remains precharged to a logic 1. Cells in the bottom sub-array operate in the same manner.

The precharge signal 412 is designed to mimic a nominal bitline slew. This helps to block early reads where the local bitline slew is faster, since NFET 410 remains active while precharge signal 412 is high. The precharge signal also helps to suppress false reads caused by leakage or noise on unselected local bitlines. Also shown in FIG. 4 are the write enable signals wrtn_top and wrtn_bot which allow the data in signals dit and dic to be written to the cells.

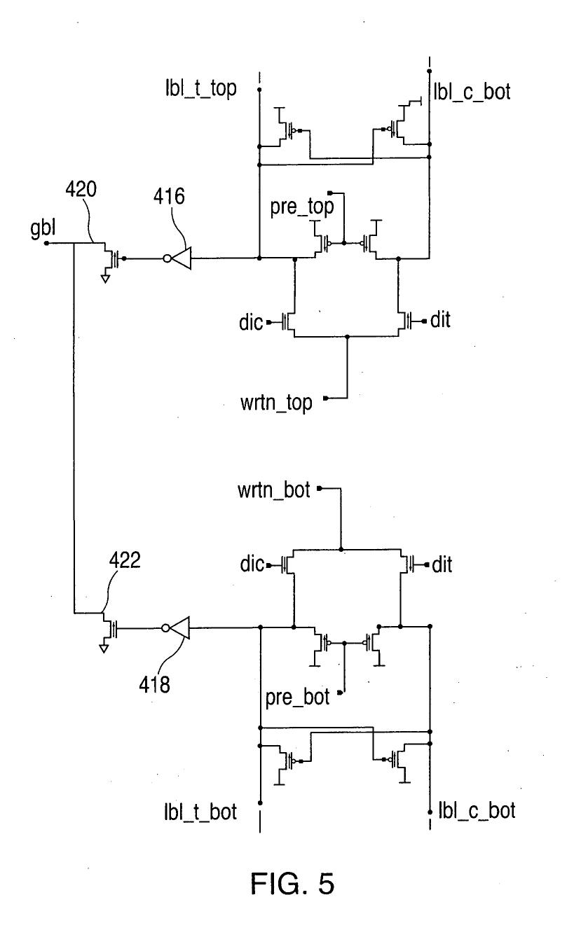

FIG. 5 depicts a local to global bitline interface in an alternate embodiment. The interface in FIG. 5 uses two inverters 416 and 418 to drive NFET devices 420 and 422, respectively. Again, the global bitline 402 is precharged to a logic 1. When the top sub-array cell stores a logic 0, inverter 416 outputs a logic 1. This causes NFET device 420 to turn on and couple the global bit line 402 to ground. When the top sub-array cell stores a logic 1, inverter 416 outputs a logic 0, turning off NFET device 420, and the global bitline 402 is precharged to a logic 1. Cells in the bottom sub-array operate in the same manner.

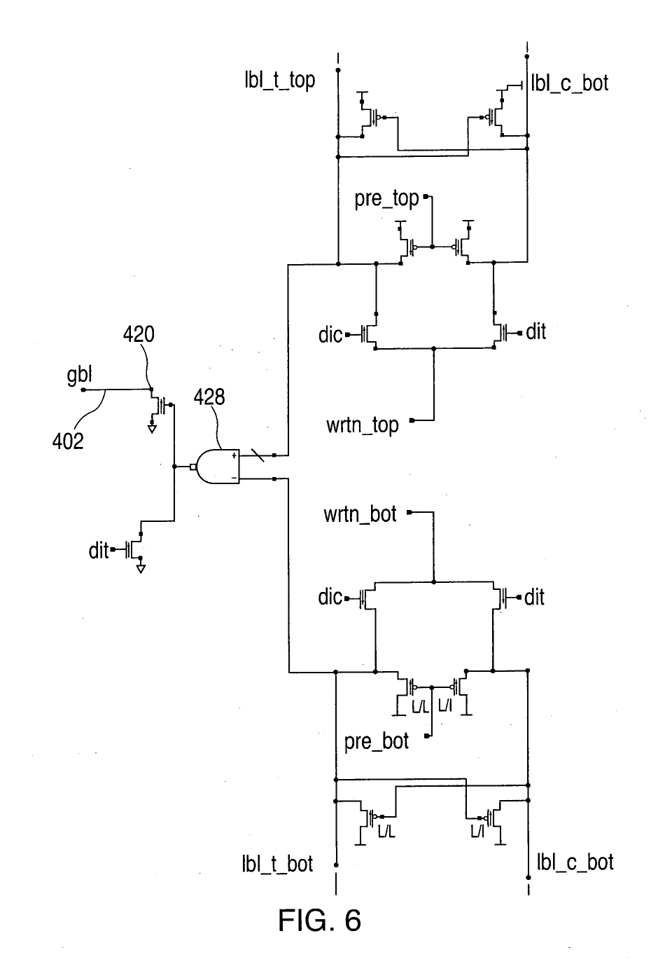

FIG. 6 depicts a local to global bitline interface in an alternate embodiment. The interface in FIG. 6 uses a NAND gate 428 to drive NFET device 420. Again, the global bitline 402 is precharged to a logic 1. When the top sub-array cell stores a logic 0, inverter NAND gate 428 outputs a logic 1. This causes NFET device 420 to turn on and couple the global bit line 402 to ground. When the top sub-array cell stores a logic 1, NAND gate 428 outputs a logic 0, turning off NFET device 420, and the global bitline 402 is precharged to a logic 1. Cells in the bottom sub-array operate in the same manner.

The design in FIG. 5 uses multiple devices, namely inverters and NFETs, to couple the local bitlines from the sub-arrays to the global bitline. This increases capacitance on the local bitlines and global bitlines. The solution of FIG. 6 reduces the global bitline capacitance by using a single device 420 driven by the NAND gate 428, to couple local bitlines. This reduces global bitline capacitance, but takes up more space and places a higher load on the local bitlines. The embodiment of FIG. 4 provides a lower device count and a higher circuit density than the designs of FIGS. 5 and 6. This reduces capacitances and area which leads to faster accessing of the memory array.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A circuit for interfacing local bitlines to a global bitline, the circuit comprising:
a first device having an input coupled to a first local bitline in a first memory sub-array;
a second device having an input coupled to a second local bitline in a second memory sub-array;
an interface line coupled to an output of the first device and coupled to an output of the second device;
a precharge device coupled to the interface line, the precharge device coupling the interface line to ground in response to a precharge signal; and
a global output device having an input coupled to the interface line and an output coupled to the global bitline.

2. The circuit of claim 1 wherein:
the first device is a PFET.

3. The circuit of claim 1 wherein:
the second device is a PFET.

4. The circuit of claim 1 wherein:
the first device is a PFET and the second device is a PFET.

5. The circuit of claim 1 wherein:
the precharge device is an NFET.

6. The circuit of claim 1 wherein:
the global output device is an NFET.

7. A circuit for interfacing local bitlines to a global bitline, the circuit comprising:
a first PFET having a gate node coupled to a first local bitline in a first memory sub-array;
a second PFET having a gate node coupled to a second local bitline in a second memory sub-array;
an interface line coupled to a drain node of the first PFET and coupled to a drain node of the second PFET;
a precharge NFET having a drain node coupled to the interface line, the precharge NFET receiving a precharge signal on a gate node and coupling the interface line to ground in response to a precharge signal; and
a global output NFET having a gate node coupled to the interface line and a drain node coupled to the global bitline.

8. A memory comprising:
a memory array having a plurality of cells coupled to bitlines;
a circuit for interfacing local bitlines to a global bitline, the circuit including:
a first device having an input coupled to a first local bitline in a first memory sub-array;
a second device having an input coupled to a second local bitline in a second memory sub-array;
an interface line coupled to an output of the first device and coupled to an output of the second device;
a precharge device coupled to the interface line, the precharge device coupling the interface line to ground in response to a precharge signal; and
a global output device having an input coupled to the interface line and an output coupled to the global bitline.

9. The memory of claim 8 wherein:
the first device is a PFET.

10. The memory of claim 8 wherein:
the second device is a PFET.

11. The memory of claim 8 wherein:
the first device is a PFET and the second device is a PFET.

12. The memory of claim 8 wherein:
the precharge device is an NFET.

13. The memory of claim 8 wherein:
the global output device is an NFET.
